(19) United States
(12) Patent Application Publication
(10) Pub. No.: US 2026/0189318 A1
(43) Pub. Date: Jul. 2, 2026

(54) ADAPTIVE EQUALIZATION CIRCUIT, ADAPTIVE EQUALIZATION METHOD, AND RECEPTION DEVICE

(71) Applicant: NTT Innovative Devices Corporation, Yokohama-shi, Kanagawa (JP)

(72) Inventors: Tomohiro TAKAMUKU, Kanagawa (JP); Mitsuteru YOSHIDA, Kanagawa (JP); Kazuhito TAKEI, Kanagawa (JP); Tsutomu TAKEYA, Kanagawa (JP)

(73) Assignee: NTT Innovative Devices Corporation, Yokohama-shi, Kanagawa (JP)

(21) Appl. No.: 19/129,739

(22) PCT Filed: Nov. 7, 2023
(86) PCT No.: PCT/JP2023/040111

§ 371 Date: May 14, 2025

(30) Foreign Application Priority Data
Nov. 24, 2022 (JP) 2022-187663

(51) Int. Cl. H04J 14/06; H03H 21/00; H04B 10/61

(52) U.S. Cl. CPC H04J 14/06; H03H 21/0012; H04B 10/6161

(57) ABSTRACT

Adaptive equalization circuitry includes: a digital filter receiving a first polarization signal and a second polarization signal subjected to polarization separation and performing further polarization separation processing; filter tap coefficient update circuitry updating a tap coefficient of the digital filter according to fluctuation in a polarization state; a polarization, separation monitor comparing a correlation value between the first polarization signal and the second polarization signal output from the digital filter with a predetermined value; and control circuitry causing the filter tap coefficient update circuitry to execute initial convergence of the tap coefficient again when the polarization separation monitor detects that the correlation value exceeds the predetermined value.

### FIELD

The present disclosure relates to an adaptive equalization circuit, an adaptive equalization method, and a reception device that compensate for a characteristic of an optical transmission line in data communication.

### BACKGROUND ART

In coherent optical communication, distortion of a transmission signal is compensated by digital signal processing on a reception side to implement large capacity transmission at several tens of Gbit/s or more. In the digital signal processing, processing such as chromatic dispersion compensation, frequency control/phase adjustment, polarization demultiplexing, and polarization dispersion compensation has been mainly performed.

The processing of the polarization demultiplexing and the polarization dispersion compensation is mainly performed by an adaptive equalizer. When the adaptive equalizer is implemented by digital signal processing, a digital filter is generally used. Distortion of a transmission signal can be compensated by setting, in the digital filter, a tap coefficient of a filter calculated such that the distortion of the transmission signal is offset. The tap coefficient of the digital filter is equivalent to an impulse response of a filter characteristic. The tap coefficient is sequentially updated to be adapted to a situation that temporally changes. The adaptive equalizer performs compensation following fluctuation in a polarization state.

In a reception optical module, an X polarization signal (hereinafter referred to as X polarization) and a Y polarization signal (hereinafter referred to as Y polarization) combined on a transmission side are separated. However, a part of a signal of the Y polarization remains in the separated X polarization and a part of a signal of the X polarization remains in the separated Y polarization. In order to further separate data of the X polarization and data of the Y polarization, a digital filter in adaptive equalization is configured by four filters in total including two filters that output X polarization data input in an X polarization direction and a Y polarization direction and two filters that output Y polarization data input in the X polarization direction and the Y polarization direction.

A sequential update algorithm explained below is used for tap coefficient update of these digital filters. In general, RLS (Recursive Least-Squares), LMS (Least Mean Square), or the like is used for the sequential update algorithm. This is an algorithm for inserting a known signal such as a training signal or a pilot signal into an optical signal on a transmission side and updating and calculating a tap coefficient for each step size to minimize an error between the transmitted known signal and a true value (a value inserted on the transmission side) of the known signal.

As the sequential update algorithm, recently, a blind equalization scheme for calculating a tap coefficient without using a known signal is also used. As examples of the blind equalization scheme, there are a constant envelope reference algorithm (CMA: Constant Modulus Algorithm) and RDE (Radius directed equalization) extended to rings having a plurality of amplitudes in order to use the CMA in QAM (Quadrature Amplitude Modulation) (for example, see PTL 1 and PTL 2). In the CMA and the RDE, the tap coefficient is updated to minimize an error between output of the digital filter and a value that the output originally should be (“a value that the output should be” can be easily estimated as, in the case of a constant envelope, a desired value of amplitude). The tap coefficient is controlled to converge according to this algorithm.

However, equivalence convergence sometimes occurs in the sequential update algorithm, in particular, the blind equalization scheme explained above. The equivalence convergence refers to a state in which wrong convergence occurs in a convergence process of an algorithm and filter outputs of X polarization data and Y polarization data are similar values. Principally, both the outputs are sometimes values biased to the X polarization data or values biased to the Y polarization data. In this case, polarization separation of the X polarization data and the Y polarization data is not correctly performed. That is, the equivalence convergence is an indicator for checking whether the polarization separation has been successfully implemented when the tap coefficient has been set in the adaptive equalization.

The occurrence of the equivalence convergence is determined from a correlation value of output information of the adaptive equalization of the X polarization data and the Y polarization data and indicates that the polarization separation has not been successfully performed. A probability of the occurrence of the equivalence convergence is high particularly in the blind equalization scheme (the CMA and the RDE). When the equivalence convergence occurs, the occurrence is detected and the sequential update algorithm is performed again. At this time, a function of detecting the occurrence of the equivalence convergence is called equivalence convergence monitor (MCC: Miss Capture Checker).

### CITATION LIST

### Patent Literature

[PTL 1] JP 2012-124782 A
[PTL 2] JP 2021-190787 A

### SUMMARY OF THE INVENTION

### Problems to be Solved by the Invention

However, in the MCC of the related art, depending on a modulation scheme, the equivalence convergence is sometimes detected by mistake even in a state in which the tap coefficient for polarization separation correctly converges and the polarization separation can be appropriately performed. That is, the equivalence conversion sometimes cannot be accurately detected depending on a modulation scheme. In this case, the update is sometimes frequently performed in a state in which the tap coefficient update is unnecessary, making adaptive equalization processing unstable.

The present disclosure has been made in order to solve the problems described above, and an object of the present disclosure is to obtain an adaptive equalization circuit, an adaptive equalization method, and a reception device that can highly accurately detect equivalence convergence for a wide varieties of types of modulation schemes and stably perform adaptive equalization processing.

### Solution to Problem

An adaptive equalization circuit according to the present disclosure includes: a digital filter receiving a first polarization signal and a second polarization signal subjected to polarization separation and performing further polarization separation processing; a filter tap coefficient update circuit updating a tap coefficient of the digital filter according to fluctuation in a polarization state; a polarization separation monitor comparing a correlation value between the first polarization signal and the second polarization signal output from the digital filter with a predetermined value; and a control circuit causing the filter tap coefficient update circuit to execute initial convergence of the tap coefficient again when the polarization separation monitor detects that the correlation value exceeds the predetermined value, wherein the polarization separation monitor includes a sign determination circuit determining to which quadrant among four quadrants on a IQ plane the first polarization signal and the second polarization signal belong, a correlation calculation circuit calculating the correlation value from a determination result of the sign determination circuit, and a comparison circuit comparing the correlation value with the predetermined value, and in case of a transmission modulation scheme in which on-axis data located on an I axis or a Q axis of the IQ plane is present in the first polarization signal and the second polarization signal, the sign determination circuit extracts the on-axis data, and associates, without overlap, data on a positive side on the I axis, data on a negative side on the I axis, data on a positive side on the Q axis, and data on a negative side on the Q axis among the on-axis data respectively with one value among values indicating the four quadrants on the IQ plane.

### Advantageous Effects of Invention

In the present disclosure, equivalence convergence can be detected with high accuracy for a wide range of modulation schemes and stable adaptive equalization processing can be performed.

### BRIEF DESCRIPTION OF THE DRAWINGS

FIG. 1 is a block diagram illustrating an optical communication system according to an embodiment.

FIG. 2 is a diagram illustrating the adaptive equalization circuit according to the embodiment.

FIG. 3 is a diagram illustrating the digital filter according to the embodiment.

FIG. 4 is a diagram illustrating a polarization separation monitor according to the embodiment.

FIG. 5 is a diagram illustrating the sign determination circuit according to the embodiment.

FIG. 6 is a flowchart of an operation of the sign determination unit X.

FIG. 7 is a flowchart of an operation of the sign determination unit Y.

FIG. 8 is a diagram illustrating a first operation example of the sign determination circuit.

FIG. 9 is a diagram illustrating a second operation example of the sign determination circuit.

FIG. 10 is a diagram illustrating a third operation example of the sign determination circuit.

FIG. 11 is a diagram illustrating a third operation example of the sign determination circuit.

FIG. 12 is a diagram illustrating a comparative example of the sign determination of the 8QAM.

FIG. 13 is a diagram illustrating a function evaluation result in the 8QAM of the adaptive equalization circuit according to the embodiment.

FIG. 14 is a diagram illustrating a function evaluation result in the 8QAM of the adaptive equalization circuit according to the embodiment.

FIG. 15 is a diagram illustrating a function evaluation result in the 8QAM of the adaptive equalization circuit according to the embodiment.

FIG. 16 is a diagram illustrating a function evaluation result in the 8QAM of the adaptive equalization circuit according to the embodiment.

### DESCRIPTION OF EMBODIMENTS

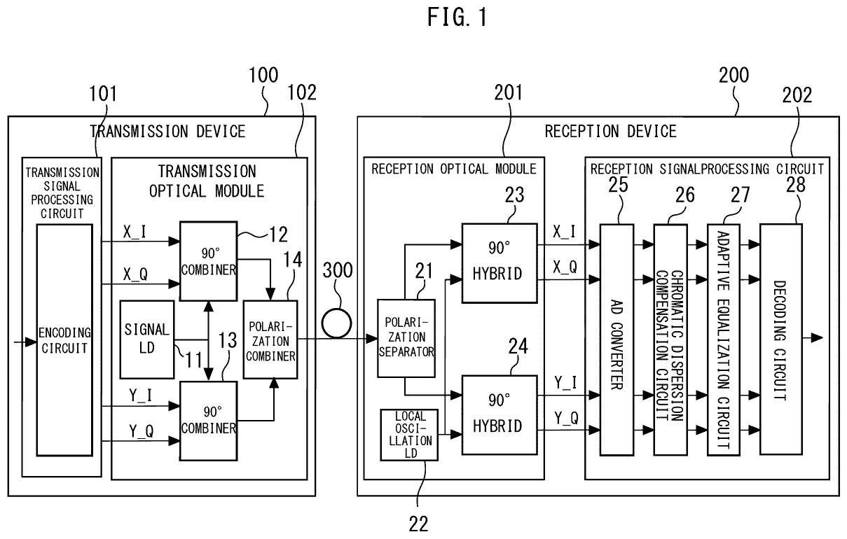

FIG. 1 is a block diagram illustrating an optical communication system according to an embodiment. The optical communication system includes a transmission device 100 and a reception device 200. An optical signal output from the transmission device 100 is transmitted to the reception device 200 through an optical fiber transmission line 300.

The transmission device 100 includes a transmission signal processing circuit 101 and a transmission optical module 102. The reception device 200 includes a reception optical module 201 and a reception signal processing circuit 202. The transmission signal processing circuit 101 applies predetermined processing to input data. Specifically, the transmission signal processing circuit 101 divides the input data into data for horizontal polarization X and data for vertical polarization Y and performs processing such as error correction encoding, band limiting filtering, and mapping for modulation on each of the data. The data for horizontal polarization X and the data for vertical polarization Y subjected to such processing are respectively represented by in-phase components and orthogonal components and output to the transmission optical module 102. An in-phase component of the data for horizontal polarization X is represented by X_I and an orthogonal component of the data for horizontal polarization X is represented by X_Q. An in-phase component of the data for vertical polarization Y is represented by Y_I and an orthogonal component of the data for vertical polarization Y is represented by Y_Q. These data components are denoted by the same signs in the reception device 200 explained below.

Note that, in the present specification, in principle, “data” indicates “baseband data” and “signal” indicates “optical signal” or “high-frequency signal”. However, “X polarization” and “Y polarization” sometimes indicate the baseband data or the high-frequency signal.

The transmission optical module 102 converts the data for horizontal polarization X and the data for vertical polarization Y respectively into an X polarization signal and a Y polarization signal, which are optical signals, and combines and transmits these two polarization signals. The transmission optical module 102 includes a signal light source 11 (a signal LD), two 900 combiners 12 and 13, and a polarization combiner 14. The two 900 combiners 12 and 13 modulate output light of the signal light source 11 respectively with the data for horizontal polarization X and the data for vertical polarization Y and convert the output light into optical signals. The polarization combiner 14 combines an X polarization signal and a Y polarization signal converted into optical signals. The combined optical signals are transmitted to the reception device 200 through the optical fiber transmission line 300.

In the reception device 200, the reception optical module 201 receives an optical signal and converts the received optical signal into an electric signal and outputs the electric signal. The reception optical module 201 includes a polarization separator 21, a local oscillation light source 22 (a local oscillation LD), and two 90° hybrid circuits 23 and 24. The polarization separator 21 separates the optical signal into an X polarization signal and a Y polarization signal, which are two orthogonal polarization components.

The 90° hybrid circuits 23 and 24 combine output light of the local oscillation light source 22 with the polarization signals of the optical signal output from the polarization separator 21 and further separates the polarization signals of the optical signal into an in-phase component I and an orthogonal component Q. Note that the 90° hybrid circuits 23 and 24 include photoelectric converters, which are not illustrated in the figure. The photoelectric converters convert components (I and Q) of the X polarization signal and the Y polarization signal, which are the optical signals, output from the 90° hybrid circuits 23 and 24 into electric signals and output the electric signals as X polarization data (X_I, X_Q) and Y polarization data (Y_I, Y_Q). The X polarization data and the Y Polarization data are referred to as reception signals below. Here, “data” indicates an analog baseband signal. Note that the configuration explained above for obtaining the X polarization data and the Y polarization data is an example and is not limited to the configuration explained above.

The reception signal processing circuit 202 includes an AD converter 25, a chromatic dispersion compensation circuit 26, an adaptive equalization circuit 27, and a decoding circuit 28. The AD converter 25 converts an electric signal output from the reception optical module 201 into a digital signal. When an optical signal propagates on the optical fiber transmission line 300, a signal waveform is distorted by chromatic dispersion. The chromatic dispersion compensation circuit 26 estimates magnitude of distortion of a reception signal from the digital signal output from the AD converter 25 and compensates for distortion due to chromatic dispersion of the digital signal.

Until the transmission device 100 combines and transmits the X polarization signal and the Y polarization signal and the reception device 200 separates the X polarization signal and the Y polarization signal, polarization fluctuation is caused by a polarization mode dispersion effect of the optical fiber transmission line 300 and a signal waveform is distorted. The adaptive equalization circuit 27 performs equalization processing for compensating for distortion due to polarization fluctuation of an output signal of the chromatic dispersion compensation circuit 26. Note that, although the polarization separation is performed by the reception optical module 201 first, the polarization separation is processed in a more complete direction by the adaptive equalization circuit 27. The decoding circuit 28 decodes a reception signal output from the adaptive equalization circuit 27 and reproduces original data (that is, input data of the transmission signal processing circuit 101).

Until data is decoded by the decoding circuit 28, inputs and outputs of processing circuits of the reception signal processing circuits 202 are represented by four signals of the in-phase component X_I and the orthogonal component X_Q of the X polarization data and the in-phase component Y_I and the orthogonal component Y_Q of the Y polarization data. In the processing circuits, in general, the X polarization data and the Y polarization data are often processed while being respectively kept separated into the in-phase components and the orthogonal components. The X polarization data (X_I, X_Q) and the Y polarization data (Y_I, Y_Q) are coordinate data. However, in the decoding circuit 28, the X polarization data (X_I, X_Q) and the Y polarization data (Y_I, Y_Q) are converted into logical data of “1” and “0”.

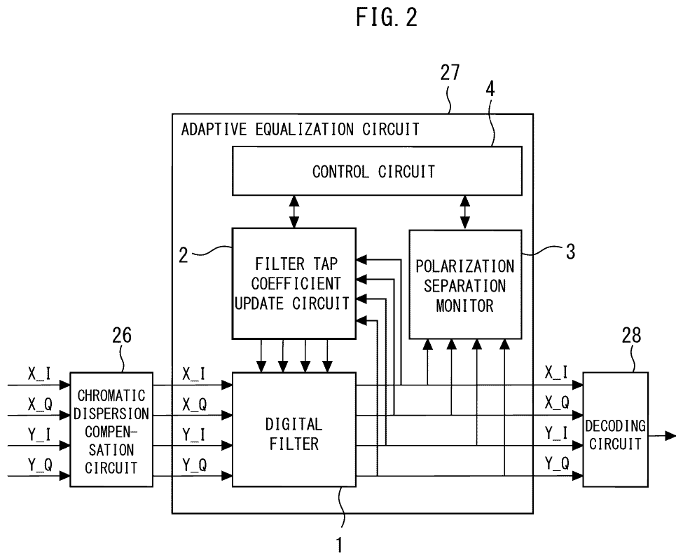

FIG. 2 is a diagram illustrating the adaptive equalization circuit according to the embodiment. The adaptive equalization circuit 27 includes a digital filter 1, a filter tap coefficient update circuit 2, a polarization separation monitor 3, and a control circuit 4.

The digital filter 1 receives input of a first polarization signal and a second polarization signal subjected to polarization separation by the chromatic dispersion compensation circuit 26 and performs further polarization separation processing to compensate for distortion and the like. A result of the compensation is supplied to the filter tap coefficient update circuit 2. A signal received via the optical fiber transmission line 300 is generally affected by fluctuation in a polarization state of the optical fiber transmission line 300. Therefore, an input signal from the chromatic dispersion compensation circuit 26 is also affected by the fluctuation in the polarization state. The filter tap coefficient update circuit 2 adaptively updates a tap coefficient of the digital filter 1 with a sequential update algorithm according to the fluctuation in the polarization state. The updated tap coefficient is set in the digital filter 1. In the sequential update algorithm, the tap coefficient is sequentially updated and converges to a predetermined value such that an output of the digital filter 1 becomes a value that the output should originally be.

At this time, the input signal to the digital filter 1 is both of the X polarization data and the Y polarization data. While the update of the filter tap coefficient is performed in the filter tap coefficient update circuit 2, the output of the digital filter 1 is supplied to the polarization separation monitor 3 as well. The polarization separation monitor 3 is called equivalence convergence monitor (MCC). The polarization separation monitor 3 always calculates a correlation value between the X polarization data and the Y polarization data output from the digital filter 1 and compares the correlation value with a predetermined value to monitor whether the X polarization data and the Y polarization data are appropriately subjected to polarization separation. When the X polarization data and the Y polarization data are not appropriately subjected to polarization separation, a correlation equal to or larger than a threshold occurs between the X polarization data and the Y polarization data. The polarization separation monitor 3 determines a failure in the polarization separation according to the correlation. When the failure in the polarization separation is determined, the control circuit 4 causes the filter tap coefficient update circuit 2 to execute initial conversion of the tap coefficient again. The initial conversion indicates monitoring of a control circuit that determines whether the polarization separation has been successful, regeneration of a Wiener filter by a least-square method, and execution of a sequential update algorithm (CMA or RDE) from a tap coefficient in an impulse state (a state in which 1 is set only in a center tap) or some processing from a state of a current tap, for example, for holding only a tap on a polarization side where the amplitude of the tap coefficient is large and re-executing the tap coefficient on the other polarization side from the tap coefficient in the impulse state.

However, actually, a frequency error compensation circuit and a carrier phase reproduction circuit not illustrated in the figure are provided on the output side of the digital filter 1. A frequency and a phase of a carrier are synchronized by these circuits. The X polarization data and the Y polarization data after the carrier synchronization are supplied to the polarization separation monitor 3 and the decoding circuit 28.

Note that a monitor operation of the polarization separation monitor 3 sometimes performs wrong detection with a modulation scheme. In general, in the case of modulation schemes such as QPSK and 16QAM, the monitor rarely malfunctions. However, in particular, in a modulation scheme such as 8QAM including a signal in which transmission side data is mapped to a point where a value of an in-phase component or an orthogonal component is near 0, the monitor sometimes malfunctions. When the monitor malfunctions, unnecessary update of the tap coefficient is repeated and an adaptive equalization operation becomes unstable.

In contrast, the polarization separation monitor 3 according to the present embodiment can reduce malfunctions of a monitor function in all modulation schemes. Further, the adaptive equalization circuit 27 using the polarization separation monitor 3 can appropriately determine polarization separation, always appropriately update a filter tap coefficient, and perform a stable adaptive equalization operation. Output of the digital filter 1 in which the tap coefficient is appropriately updated in this way is supplied to the decoding circuit 28 illustrated in FIG. 2 as a compensated reception signal.

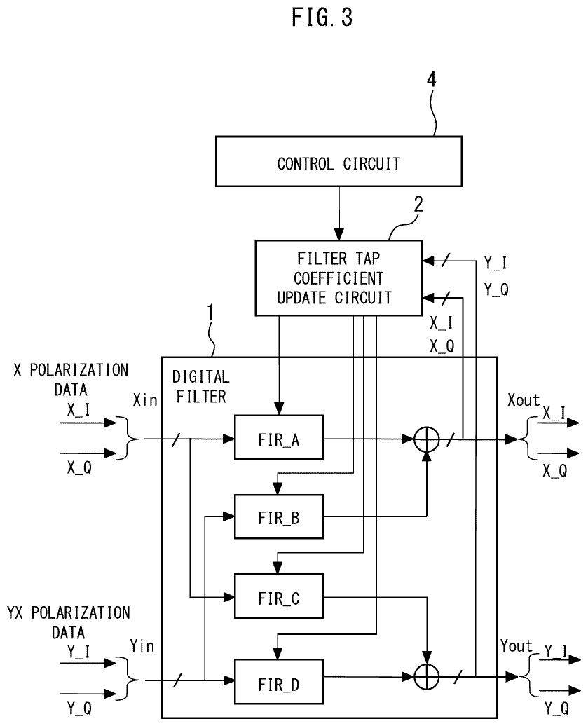

FIG. 3 is a diagram illustrating the digital filter according to the embodiment. The digital filter 1 is an example configured by an FIR filter. However, the digital filter 1 is not limited to this configuration and only has to be a configuration in which wrong convergence can occur in the case of a sequential update algorithm in which a tap coefficient of a filter is calculated by a convergence operation of a convergence algorithm.

As an example of the sequential update algorithm, there is a blind equalization scheme such as a CMA (Constant Modulus Algorithm) or RDE (Radius directed equalization). In these schemes, the tap coefficient is updated to minimize an error between output of the digital filter 1 and a value that the output should originally be (“a value that the output should be” can be easily estimated as, in the case of a constant envelope, a desired value of amplitude). As another example, there are RLS (Recursive Least-Squares), LMS (Least Mean Square), or the like. These algorithms are algorithms for inserting a known signal such as a training signal or a pilot signal into an optical signal on a transmission side and updating a tap coefficient for each step size to minimize an error between the transmitted known signal and a true value (a value set on the transmission side) of the known signal.

The digital filter 1 includes FIR (Finite Impulse Response) filters FIR_A, FIR_B, FIR_C, and FIR_D configured in a butterfly shape. Each of the FIR filters includes N taps. However, the numbers of taps of the FIR filters may be different from one another. FIR_A is a filter for the X polarization data. FIR_B is a filter for the influence of the Y polarization data on the X polarization data. FIR_C is a filter for the influence of the X polarization data on the Y polarization data. FIR_D is a filter for the Y polarization data.

The digital filter 1 sets an addition value of a filtering result of FIR_A for the X polarization data and a filtering result of FIR_B for the Y polarization data as a compensation output of the X polarization data and sets an addition value of a filtering result of FIR_C for the X polarization data and a filtering result of FIR_D for the Y polarization data as a compensation output of the Y polarization data. Accordingly, the polarization separation is further ensured.

The digital filter 1 sets an addition value of a filtering result of FIR_A for the X polarization data and a filtering result of FIR_B for the Y polarization data as a compensation output of the X polarization data and sets an addition value of a filtering result of FIR_C for the X polarization data and a filtering result of FIR_D for the Y polarization data as a compensation output of the Y polarization data. Accordingly, the polarization separation is further ensured.

A filter tap coefficient of the digital filter 1 is calculated and set by the filter tap coefficient update circuit 2. When the filter tap coefficient is calculated and set, tap coefficients of FIR_A, FIR_B, FIR_C, and FIR_D are indicated by the following expressions.

$$WXX ( n + 1 ) = W X X ( n ) + μ eX ( n ) Xout ( n ) \cdot Xin * ( n )$$

$$WYX ( n + 1 ) = W Y X ( n ) + μ eX ( n ) Xout ( n ) \cdot Yin * ( n )$$

$$WXY ( n + 1 ) = WXY ( n ) + μ eY ( n ) Yout ( n ) \cdot Xin * ( n )$$

$$WYY ( n + 1 ) = W Y Y ( n ) + μ eY ( n ) Yout ( n ) \cdot Yin * ( n )$$

where, n is a value indicating update order in the sequential update algorithm. The tap coefficient WXX(n) indicates a tap coefficient group of FIR_A in the case of the update order n. The tap coefficient WYX(n) indicates a tap coefficient group of FIR_B in the case of the update order n. The tap coefficient WXY(n) indicates a tap coefficient group of FIR_C in the case of the update order n. The tap coefficient WYY(n) indicates a tap coefficient group of FIR_D in the case of the update order n. μ indicates a step size of the update algorithm. eX(n) indicates an error between a filter output of the X polarization data and a desired value. eY(n) indicates an error between a filter output of the Y polarization data and a desired value. Xout(n) indicates a filter output in the X polarization data. Xin(n) indicates a filter input in the X polarization data. Yout(n) indicates a filter output in the Y polarization data. Yin(n) indicates a filter input in the Y polarization data. * indicates conjugate or complex conjugate. Note that the data and the tap coefficients are represented by complex numbers.

The update of the tap coefficient is sequentially performed in the update order n according to the sequential update algorithm explained above and, finally, the tap coefficient converges. A condition of the convergence is determined by the number of times of the update order n, the error between the filter output and the desired value, or the like. Note that the expressions described above are an example of expressions representing the sequential update algorithm. The expressions representing the sequential update algorithm are not limited to the expressions described above.

The above explanation indicates the case in which the tap coefficient is updated after the convergence. However, the tap coefficient can also be sequentially updated during the convergence. That is, it is also possible to adopt a method of sequentially updating the tap coefficient calculated to minimize, even if the convergence condition is not achieved, in a state in which a polarization state fluctuates, a difference between output of the digital filter and a value that the output should be.

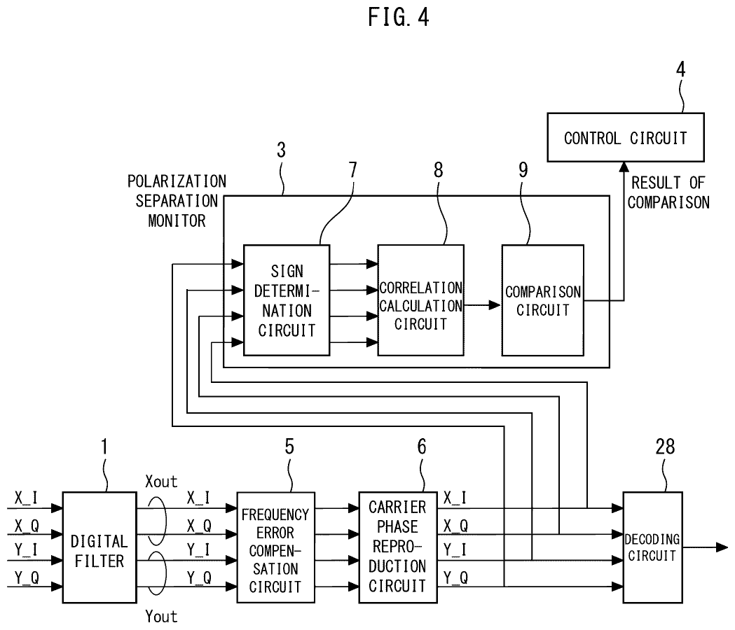

FIG. 4 is a diagram illustrating a polarization separation monitor according to the embodiment. In FIG. 4, a frequency error compensation circuit 5 and a carrier phase reproduction circuit 6 not illustrated in FIG. 2 are connected between the digital filter 1 and the decoding circuit 28. The frequency error compensation circuit 5 is a circuit that reduces a frequency error between a transmission carrier and a receiver carrier to substantially zero. The carrier phase reproduction circuit 6 is a circuit that reduces a phase error between the carriers to substantially zero. With the frequency error compensation circuit 5 and the carrier phase reproduction circuit 6, the X polarization data and the Y polarization data from the digital filter 1 can be stably displayed on an IQ plane without phase rotation and phase shift. Accordingly, the X polarization data and the Y polarization data from the digital filter 1 can be accurately processed in the polarization separation monitor 3 and the decoding circuit 28. Note that, when phase rotation and phase shift can be eliminated by another method, the frequency error compensation circuit 5 and the carrier phase reproduction circuit 6 are not essential for the adaptive equalization circuit 27.

The polarization separation monitor 3 includes a sign determination circuit 7, a correlation calculation circuit 8, and a comparison circuit 9. The sign determination circuit 7 determines signs of outputs Xout and Yout of the digital filter 1 supplied via the frequency error compensation circuit 5 and the carrier phase reproduction circuit 6. Here, a case in which the outputs Xout and Yout of the digital filter 1 are shown on the IQ plane is conceived. Specifically, Xout has an I-axis component X_I and a Q-axis component X_Q and Yout has an I-axis component Y_I and a Q-axis component Y_Q. The sign determination circuit 7 determines, for each bit or each symbol, to which quadrant among four quadrants on the IQ plane received X polarization data and received Y polarization data belong. Note that in the case of multi-value modulation such as QPSK or 16QAM, the symbol indicates a unit of a change in a phase or amplitude. Two bits are one symbol in the QPSK and four bits are one symbol in the 16QAM.

The correlation calculation circuit 8 calculates a correlation value between the X polarization data and the Y polarization data from a determination result of the sign determination circuit 7. The correlation value is higher as the X polarization data and the Y polarization data are closer to the same value. The comparison circuit 9 compares the correlation value calculated by the correlation calculation circuit 8 with a predetermined value and notifies a result of the comparison to the control circuit 4.

When the correlation value exceeds the predetermined value, the control circuit 4 regards that there is a correlation between the X polarization data and the Y polarization data and determines that convergence of a tap coefficient was not appropriately performed. Therefore, when the polarization separation monitor 3 detects that the correlation value exceeds the predetermined value, the control circuit 4 causes the filter tap coefficient update circuit 2 to execute initial convergence of the tap coefficient again. On the other hand, if the correlation value from the correlation calculation circuit 8 is smaller than the predetermined value, the control circuit 4 regards that there is no correlation between the X polarization data and the Y polarization data and determines that the convergence of the tap coefficient was appropriately performed. In that case, the control circuit 4 does not instruct the filter tap coefficient update circuit 2 to execute the initial convergence of the tap coefficient again and the digital filter 1 continues use of the tap coefficient at that point in time.

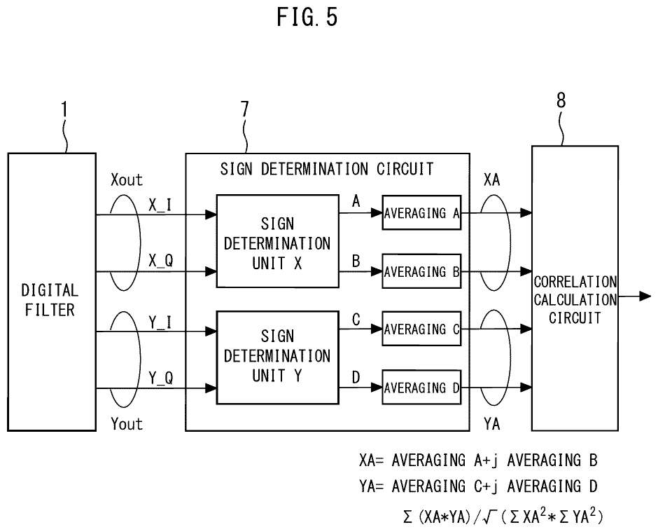

FIG. 5 is a diagram illustrating the sign determination circuit according to the embodiment. The frequency error compensation circuit 5 and the carrier phase reproduction circuit 6 are not illustrated. The sign determination circuit 7 includes sign determination units X and Y and averaging circuits A, B, C, and D.

The sign determination unit X determines, based on the I-axis component X_I and the Q-axis component X_Q of the X polarization data from the digital filter 1, to which quadrant among the four quadrants on the IQ plane the X polarization data belongs. Values indicating the four quadrants (a first quadrant, a second quadrant, a third quadrant, and a fourth quadrant) on the IQ plane are respectively (+1, +1), (−1, +1), (−1, −1), and (+1, −1). Signs in the case in which the X polarization data belongs to the first quadrant are A=−1 and B=−1. Signs in the case in which the X polarization data belongs to the second quadrant are A=−1 and B=−1. Signs in the case in which the X polarization data belongs to the third quadrant are A=−1 and B=−1. Signs in the case in which the X polarization data belongs to the fourth quadrant are A=+1 and B=−1.

The sign determination unit Y also determines, based on the I-axis component Y_I and the Q-axis component Y_Q of the Y polarization data from the digital filter 1, to which quadrant among the four quadrants on the IQ plane the Y polarization data belongs. Values indicating the four quadrants (the first quadrant, the second quadrant, the third quadrant, and the fourth quadrant) on the IQ plane are respectively (+1, +1), (−1, +1), (−1, −1), and (+1, −1). Signs in the case in which the Y polarization data belongs to the first quadrant are C=+1 and D=−1. Signs in the case in which the Y polarization data belongs to the second quadrant are C=−1 and D=+1. Signs in the case in which the Y polarization data belongs to the third quadrant are C=−1 and D=−1. Signs in the case in which the Y polarization data belongs to the fourth quadrant are C=+1 and D=−1.

When the X polarization data or the Y polarization data are on-axis data present on the I axis or the Q axis, a quadrant to which the X polarization data or the Y polarization data belongs is unclear. Thus, the sign determination circuit 7 extracts on-axis data, associates, without overlap, data on the positive side on the I axis, data on the negative side on the I axis, data on the positive side on the Q axis, and data on the negative side on the Q axis among the on-axis data respectively with one value among values indicating the four quadrants on the IQ plane, and outputs signs indicating the associated quadrants. Details are explained below.

The averaging circuit A accumulates, by a predetermined number of times, the sign A determined by the sign determination unit X and outputs the sign A as averaging A. The averaging circuit B accumulates, by the predetermined number of times, the sign B determined by the sign determination unit X and outputs the sign B as averaging B. The averaging circuit C accumulates, by the predetermined number of times, the sign C determined by the sign determination unit Y and outputs the sign C as averaging C. The averaging circuit D accumulates, by the predetermined number of times, the sign D determined by the sign determination unit Y and outputs the sign D as averaging D.

Averaged data XA of the X polarization and averaged data YA of the Y polarization are represented as follows using the averaging A, the averaging B, the averaging C, and the averaging D. Note that j is an imaginary unit.

$$XA = averaging A + j averaging B$$

$$YA = averaging C + j averaging D$$

Subsequently, the averaged data XA of the X polarization and the averaged data YA of the Y polarization output from the sign determination circuit 7 are supplied to the correlation calculation circuit 8. The correlation calculation circuit 8 calculates, with the following expression, a correlation value between the averaged data XA of the X polarization and the averaged data YA of the Y polarization. “*” indicates complex multiplication.

$$Correlation value = \sum ( XA * YA ) , √ ( \sum {XA}^{2} * \sum {YA}^{2} )$$

If the X polarization data X and the Y polarization data Y are the same value in the output of the digital filter 1 (=if there is a correlation), since the averaged data XA of the X polarization and the averaged data YA of the Y polarization are the same value, the correlation value described above is unlimitedly close to 1. Note that, when signs of XA and XB are the same, the correlation value is not close to 0 and increases. On the other hand, if the X polarization data X and the Y polarization data Y are different substantially at random (=if there is no correlation), values of the averaged data XA of the X polarization and the averaged data YA of the Y polarization have different signs at a probability of ½. Accordingly, a sign of XA*YA of the numerator of the correlation value changes to the positive side and the negative side and accumulation of the sign is close to nearly 0.

Note that a cumulative number in the numerator and the denominator of the expression of the correlation value is different from the predetermined number of times in the case in which the averaging is performed in the sign determination circuit 7. For example, the averaging of the sign determination circuit 7 can be performed for each sixteen symbols and the accumulation of the expression of the correlation value can be set to 512 times. In this case, the correlation value is obtained for each 16×512=8192 symbols.

The calculation of the correlation value of the correlation calculation circuit 8 is not limited to the method explained above. If the correlation value between the X polarization data X and the Y polarization data Y, which are the output of the digital filter, can be calculated based on the averaged data XA of the X polarization and the averaged data YA of the Y polarization from the sign determination circuit 7, any arithmetic expression can be applied to the adaptive equalization circuit 27 in the present embodiment.

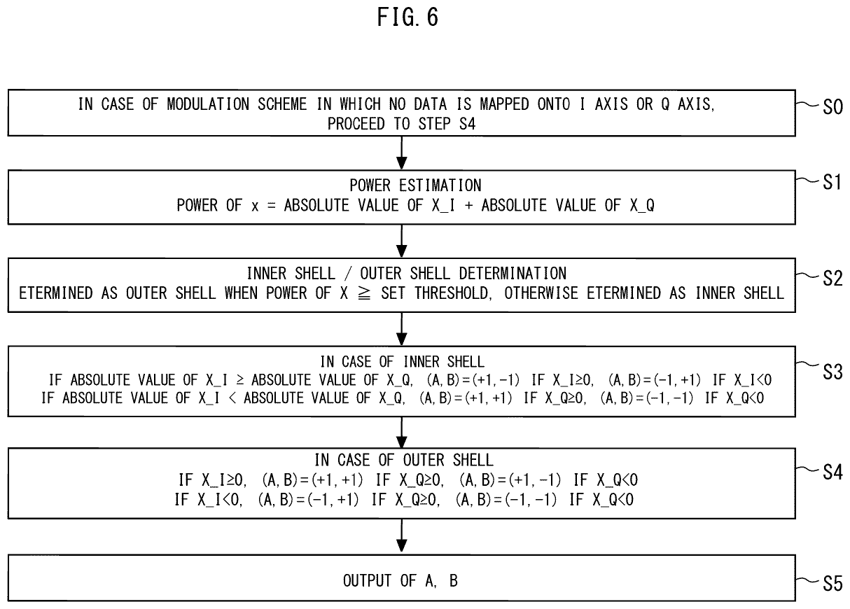

FIG. 6 is a flowchart of an operation of the sign determination unit X. Steps executed by the sign determination unit X are different depending on a modulation scheme.

Step S0: When a part of data is mapped onto the I axis or the Q axis on the IQ plane as in the case in which the modulation scheme is 8QAM, the sign determination unit X subsequently proceeds to step S1. On the other hand, when all data are not mapped onto the I axis or the Q axis on the IQ plane as in the case in which the modulation scheme is QPSK or 16QAM, the sign determination unit X skips steps S1 to S3 and proceeds to step S4.

Step S1: If the I-axis component X_I and the Q-axis component X_Q of the X polarization data are input from the digital filter 1, the sign determination unit X estimates power of the X polarization data based on the following expression.

$$Power of X polarization data = absolute value of X\_I + absolute value of X\_Q$$

In general, the power is represented by a square of a signal. In the above expression, the power can be represented as an indicator of the power. The expression described above can more easily calculate the indicator of the power because the indicator can be calculated only by addition without using multiplication. In a modulation scheme for mainly changing a phase and amplitude, in general, amplitude that data can take is divided into a several groups. In particular, amplitude that data of a modulation scheme used in the blind equalization scheme can take is narrowed down to several types. Amplitude is one type in the case of QPSK, amplitude is two types in the case of 8QAM, and amplitude is three types in the case of 16QAM. Since the calculation of the power in this step only determines to which group of amplitude data belongs, it is unnecessary to accurately measure a power value.

Step S2: The sign determination unit X determines, based on the magnitude of the power calculated in step S1, to which amplitude group the data belongs. For example, when the amplitude that the data can take is two types of an inner shell and an outer shell, if the power of X≥set threshold, the sign determination unit X determines the amplitude as the outer shell, otherwise, determines the amplitude as the inner shell.

Step S3: When determining in step S2 that the amplitude is the inner shell, the sign determination unit X determines signs A and B according to the following condition. Here, a case in which the data of the inner shell is mapped onto the I axis or the Q axis and the data of the outer shell is mapped in the four quadrants of the IQ plane is explained. Note that when the data of the inner shell is mapped in the quadrant of the IQ plane and the data of the outer shell is mapped onto the I axis or the Q axis, step S3 is executed in the case of the outer shell and step S4 is executed in the case of the inner shell.

In the case of absolute value of X_I absolute value of X_Q, if X_I≥o, the sign determination unit X determines (A, B)=(+1, −1) as the fourth quadrant and, if X_I<0, determines (A, B)=(−1, +1) as the second quadrant. In the case of absolute value of X_I<absolute value of XQ, if X_Q≥0, the sign determination unit X determines (A, B)=(+1, +1) as the first quadrant and, if X_Q<0, determines (A, B)=(−1, −1) as the third quadrant.

Step S4: When determining the amplitude as the outer shell in step S2, the sign determination unit X determines the signs A and B according to the following condition. In the case of X_I≥0, if X_Q≥0, the sign determination unit X determines (A, B)=(+1, +1) as the first quadrant and, if X_Q<0, determines (A, B)=(+1, −1) as the fourth quadrant. In the case of X_I<0, if X_Q≥0, the sign determination unit X determines (A, B)=(−1, +1) as the second quadrant and, if X_Q<0, determines (A, B)=(−1, −1) as the third quadrant.

Step S5: The sign determination unit X outputs the signs A and B calculated in step S3 or step S4. Note that the sign determination unit X can determine as follows in step S3. In the case of absolute value of X_I≥absolute value of X_Q, if X_I≥0, the sign determination unit X determines (A, B)=(+1, +1) as the first quadrant and, if X_I<0, determines (A, B)=(−1, −1) as the third quadrant. In the case of absolute value of X_I<absolute value of X_Q, if X_Q≥0, the sign determination unit X determines (A, B)=(−1, +1) as the second quadrant and, if X_Q<0, determines (A, B)=(+1, −1) as the fourth quadrant.

Note that the example explained above is the case in which the amplitude that the data can take is the two types of the inner shell and the outer shell. However, the example can also be applied to a case in which the amplitude that the data can take is three or more types. In that case, the sign determination unit X only has to determine, with the same power calculation method, which group of amplitude data belongs. After the determination of the amplitude group, concerning the on-axis data located on the I axis and the Q axis, the sign determination unit X allocates a quadrant according to step S3. Concerning data originally mapped in a quadrant, the sign determination unit X determines a quadrant according to the hard determination in step S4.

Note that association of the on-axis data located on the I axis or the Q axis with a quadrant is not limited to the two types explained above. The on-axis data may be allocated to any quadrant if different data are not associated with the same quadrant. For example, (I, Q)={(1, 0), (−1, 0), (0, 1), (0, −1)} can be associated like (A, B)={(−1, +1), (+1, −1), (−1, −1), (−1, −1)}, (A, B)={(+1, −1), (−1, +1), (−1, −1), (+1, +1)} or (A, B)={(+1, +1), (−1, +1), (−1, =1), (+1, −1)}. As explained above, if the data on the positive side on the I axis, the data on the negative side on the I axis, the data on the positive side on the Q axis, and the data on the negative side on the Q axis of the X polarization data and the Y polarization data are respectively associated with quadrants without overlap, a correlation between the X polarization data and the Y polarization data can be efficiently detected. Such optional association is the same in the sign determination unit Y explained below.

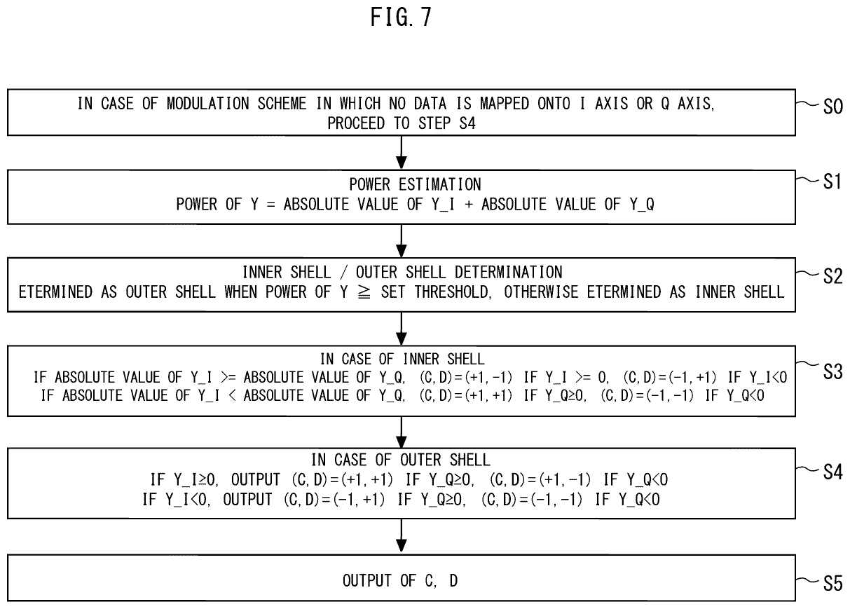

FIG. 7 is a flowchart of an operation of the sign determination unit Y. The operation of the sign determination unit Y is the same as the operation of the sign determination unit X illustrated in FIG. 6.

Step S0: When a part of data is mapped onto the I axis or the Q axis on the IQ plane as in the case in which the modulation scheme is 8QAM, the sign determination unit Y subsequently proceeds to step S1. On the other hand, when all data are not mapped onto the I axis or the Q axis on the IQ plane as in the case in which the modulation scheme is QPSK or 16QAM, the sign determination unit Y skips steps S1 to S3 and proceeds to step S4.

Step S1: If the I-axis component Y_I and the Q-axis component Y_Q of the Y polarization data are input from the digital filter 1, the sign determination unit Y estimates power of the Y polarization data based on the following.

$$Power of Y polarization data = absolute value of Y\_I + absolute value of Y\_Q$$

Note that, since the calculation of the power only determines to which group of amplitude data belongs, the power can be compared by the indicator of the above expression. Accurate measurement of a power value is unnecessary.

Step S2: The sign determination unit Y determines, based on the magnitude of the power calculated in step S1, to which amplitude group the Y polarization data belongs. For example, when amplitude that the Y polarization data can take is two types of an inner shell and an outer shell, the sign determination unit Y determines the amplitude as the outer shell if power of Y≥set threshold, otherwise, determines the amplitude as the inner shell.

Step S3: When determining in step S2 that the amplitude is the inner shell, the sign determination unit Y determines signs C and D according to the following condition. Here, a case in which data of the inner shell is mapped onto the I axis or the Q axis and data of the outer shell is mapped in the four quadrants of the IQ plane is explained. Note that, when the data of the inner shell is mapped in the quadrants on the IQ plane and the data of the outer shell is mapped onto the I axis or the Q axis, step S3 is executed in the case of the outer shell and step S4 is executed in the case of the inner shell.

In the case of absolute value of Y_I absolute value of Y_Q, if Y_I≥0, the sign determination unit Y determines (C, D)=(+1, −1) as the fourth quadrant and, if Y_I<0, determines (C, D)=(−1, +1) as the second quadrant. In the case of absolute value of Y_I<absolute value of Y_Q, if Y_Q≥0, the sign determination unit Y determines (C, D)=(+1, +1) as the first quadrant and, if Y_Q<0, determines (C, D)=(−1, −1) as the third quadrant.

Step S4: When determining the amplitude as the outer shell in step S2, the sign determination unit Y determines the signs C and D according to the following condition. In the case of Y_I≥0, if Y_Q≥0, the sign determination unit Y determine (C, D)=(+1, +1) as the first quadrant and, if Y_Q<0, determines (C, D)=(+1, −1) as the fourth quadrant. In the case of Y_I<0, if Y_Q≤0, the sign determination unit Y determines (C, D)=(−1+1) as the second quadrant and, if Y_Q<0, determines (C, D)=(−1, −1) as the third quadrant.

Step S5: The sign determination unit Y outputs the signs C and D calculated in step S3 and step S4. Note that the sign determination unit Y can also determine as follows in step S3. In the case of absolute value of Y_I absolute value of Y_Q, if Y_I≥0, the sign determination unit Y determines (C, D)=(+1, +1) as the first quadrant and, if Y_I<0, determines (C, D)=(−1, −1) as the third quadrant. In the case of absolute value of Y_I<absolute value of Y_Q, if Y_Q≥0, the sign determination unit Y determines (C, D)=(−1, +1) as the second quadrant and, if Y_Q<0, determines (C, D)=(+1, −1) as the fourth quadrant.

Note that, like the processing of the sign determination unit X, the processing of the sign determination unit Y can be applied to a case in which amplitude that data can take is three or more types. Association of the on-axis data located on the I axis or the Q axis with a quadrant is not limited to the two types explained above. The on-axis data may be allocated to any quadrant if different data are not associated with the same quadrant.

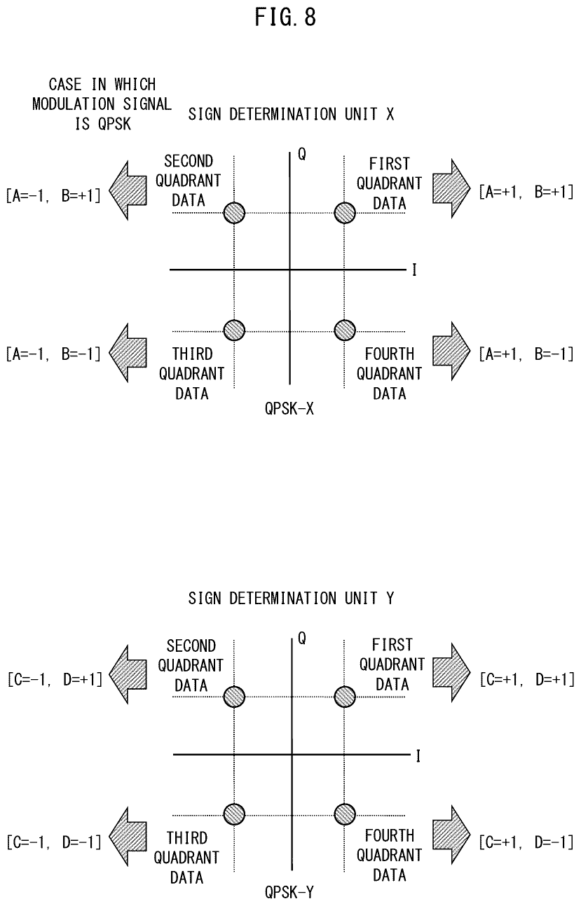

FIG. 8 is a diagram illustrating a first operation example of the sign determination circuit. The first operation example is a case in which a modulation signal is QPSK. When the modulation signal is the QPSK, since on-axis data located on the I axis or the Q axis is absent, step S4 is executed next to step S0 in the flowcharts of FIG. 6 and FIG. 7.

In step S4, in the case of X_I≥0, if X_Q≥0, the sign determination unit X determines (A, B)=(+1, +1) as the first quadrant and, if X_Q<0, determines (A, B)=(+1, −1) as the fourth quadrant. In the case of X_1<0, if X_Q≥0, the sign determination unit X determines (A, B)=(−1, +1) as the second quadrant and, if X_Q<0, determines (A, B)=(−1, −1) as the third quadrant. In the case of Y_I≥0, if Y_Q≥0, the sign determination unit Y determines (C, D)=(+1, +1) as the first quadrant and, if Y_Q<0, determines (C, D)=(+1, −1) as the fourth quadrant. In the case of Y_1<0, if Y_Q≥0, the sign determination unit Y determines (C, D)=(−1, +1) as the second quadrant and, if Y_Q<0, determines (C, D)=(−1, −1) as the third quadrant.

As a result of the above, (A, B) and (C, D) are equivalent to a result obtained by determining, on the reception side, with hard determination, a value indicating the first quadrant, a value indicating the second quadrant, a value indicating the third quadrant, and a value indicating the fourth quadrant of the QPSK. For example, a hard determination result of the value indicating the first quadrant is A=+1, B=+1, C=+1, and D+1. A hard determination result of the value indicating the second quadrant is A=−1, B=+1, C=−1, and D=−1. A hard determination result of the value indicating the third quadrant is A=−1, B=−1, C=−1, and D=−1. A hard determination result of the value indicating the fourth quadrant is A=−1, B=−1, C=−1, and D=−1.

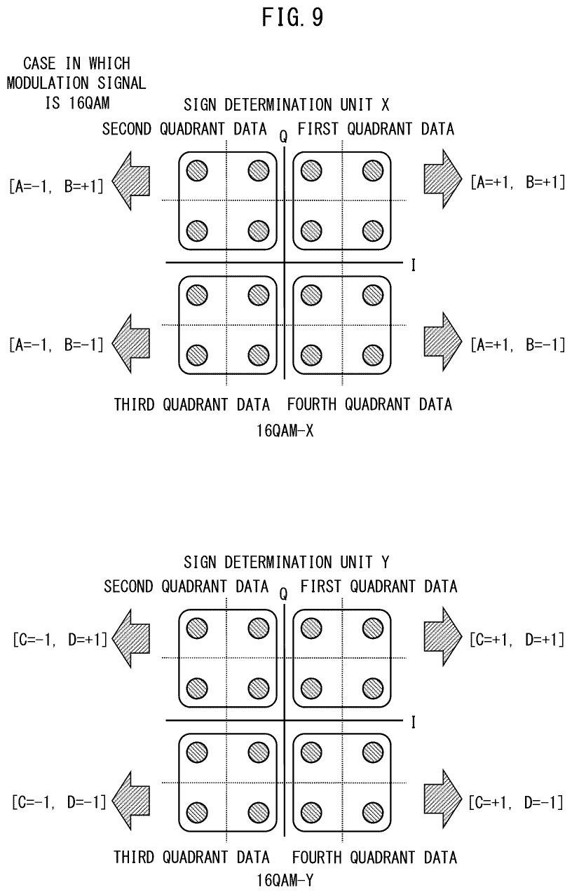

FIG. 9 is a diagram illustrating a second operation example of the sign determination circuit. The second operation example is a case in which the modulation signal is 16QAM. When the modulation signal is the 16QAM, since on-axis data located on the I axis or the Q axis is absent, step S4 is executed next to step S0 in the flowcharts of FIG. 6 and FIG. 7.

In step S4, in the case of X_I≥0, if X_Q≥0, the sign determination unit X determines(A, B)=(+1, +1) as the first quadrant and, if X_Q<0, determines (A, B)=(−1, −1) as the fourth quadrant. In the case of X_I<0, if X_Q≥0, the sign determination unit X determines (A, B)=(−1, +1) as the second quadrant and, if X_Q<0, determines (A, B)=(−1, −1) as the third quadrant. In the case of Y_I≥0, if Y_Q≥0, the sign determination unit Y determines (C, D)=(+1, +1) as the first quadrant and, if Y_Q<0, determines (C, D)=(+1,−1) as the fourth quadrant. In the case of Y_I<0, if Y_Q≥0, the sign determination unit Y determines (C, D)=(−1, +1) as the second quadrant and, if Y_Q<0, determines (C, D)=(−1, −1) as the third quadrant.

As a result of the above, (A, B) and (C, D) are equivalent to a result obtained by determining, on the reception side, with hard determination, coordinates where all sixteen data of the 16QAM are mapped on the IQ plane. For example, a hard determination result of a value indicating the first quadrant is A=+1, B=+1, C=+1, and D+1. A hard determination result of a value indicating the second quadrant is A=−1, B=+1, C=−1, and D=+1. A hard determination result of a value indicating the third quadrant is A=−1, B=−1, C=−1, and D=−1. A hard determination result of a value indicating the fourth quadrant is A=+1, B=−1, C=+1, and D=−1.

As explained above, for the data present in the four quadrants on the IQ plane, A, B, C, and D are calculated by the hard determination by the I axis and the Q axis. Therefore, in a transmission modulation scheme without on-axis data located on the I axis and the Q axis such as 64QAM or 256QAM, A, B, C. and D are calculated by the same method as the method explained above.

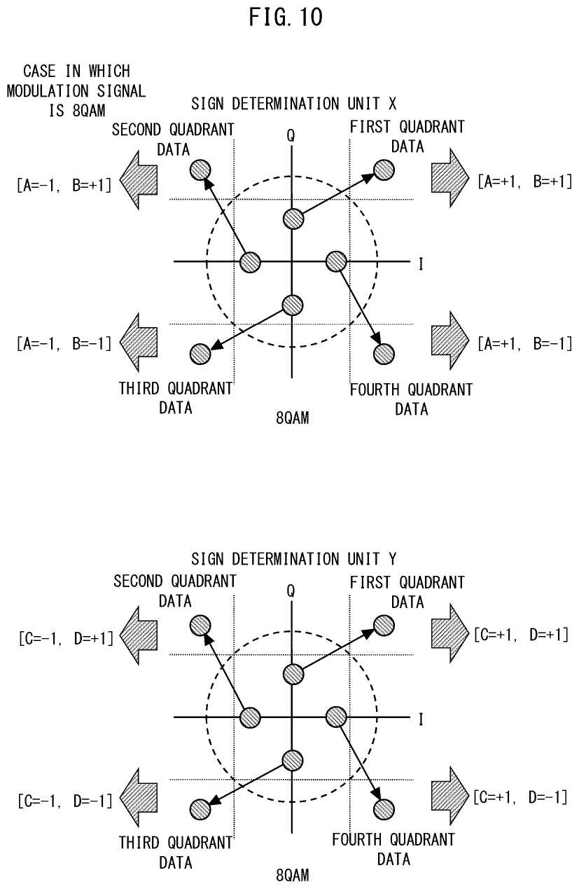

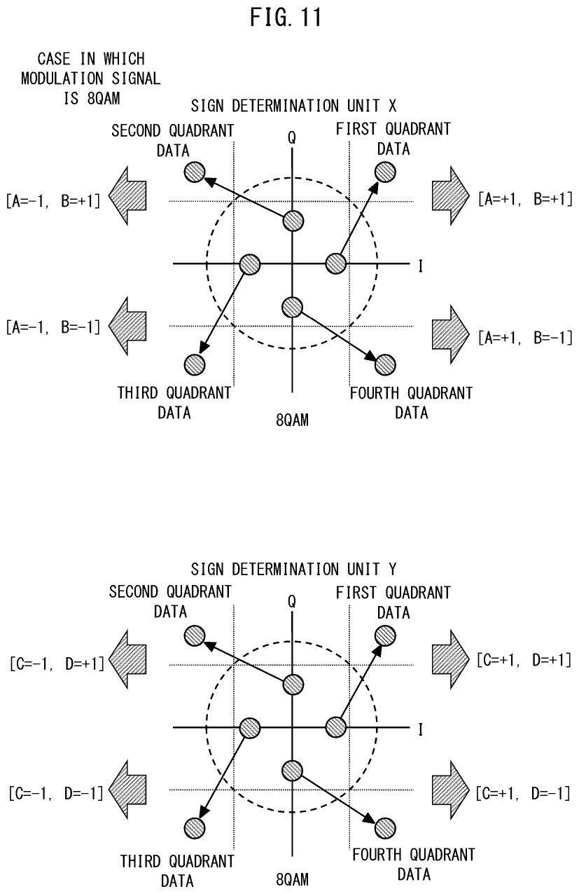

FIG. 10 and FIG. 1I are diagrams illustrating a third operation example of the sign determination circuit. The third operation example is a case in which a modulation signal is 8QAM. The 8QAM is a transmission modulation scheme in which on-axis data located on the I axis and the Q axis of the IQ plane are present in X polarization data and Y polarization data. Two examples illustrated in FIG. 10 and FIG. 11 are explained about association of the on-axis data located on the I axis and the Q axis with a quadrant. However, as explained above, the association is not limited to the two examples. Association with any quadrant is possible as long as the on-axis data do not overlap.

When the modulation scheme is the 8QAM. four data in an outer shell among eight data are mapped to the centers of the quadrants of the first to fourth quadrants. However, the remaining four data in an inner shell are mapped onto the I axis or the Q axis. Therefore, since the on-axis data located on the I axis or the Q axis is present in step S0, all the steps from step S1 of the flowcharts of FIG. 6 and FIG. 7 are executed.

Power estimation is performed in step S1. Powers of the X polarization data and the Y polarization data are respectively calculated by the following expressions.

$$Power of X polarization data = absolute value of X\_I + absolute value of X\_Q$$

$$Power of Y polarization data = absolute value of Y\_I + absolute value of Y\_Q$$

Concerning the four data in the outer shell, when the data at a reception time are located substantially in the centers of the quadrants, the absolute value of X_I and the absolute value of X_Q are substantially the same values and the absolute value of Y_I and the absolute value of Y_Q are also substantially the same value. Therefore, each of the powers is calculated as approximately a double of the absolute value of a coordinate value of the I axis.

On the other hand, for the four data in the inner shell, one of the absolute value of X_I and the absolute value of X_Q is near substantially zero and one of the absolute value of Y_I and the absolute value of Y_Q is near substantially zero. For this reason, each of the powers is calculated only as the absolute value of the coordinate value of the I axis or the absolute of the coordinate value of the Q axis.

Therefore, if it is assumed that a coordinate value of the outer sell is approximately a double of a coordinate value of the inner shell, the power of the outer shell is approximately a quadruple of the power of the inner shell. A difference between the powers can be detected relatively large. For that reason, if a threshold is set between the powers, it is possible to relatively easily determine whether reception data is data of the inner shell or data of the outer shell.

In step S2, the sign determination unit X determines whether reception data is data of the inner shell or data of the outer shell. In the case of 8QAM, as explained above, for example, if a threshold is set to 2.5 times of a coordinate value of the I axis of the data of the inner shell, when the power estimated in step S1 is higher than the set threshold, the reception data is determined as data of the outer shell and, when the power is lower than the set threshold, the reception data is determined as data of the inner shell. Note that the threshold is selected as, according to a modulation scheme, a value that can more securely determine the inner shell and the outer shell. According to the determination, in an example of the 8QAM illustrated in FIG. 10, data located near the centers of the four quadrants on the IQ plane are identified as data of the outer shell and on-axis data located on the I axis or the Q axis is identified as data of the inner shell.

In step S3, the following processing is performed on the data of the inner shell. In the case of absolute value of X_I absolute value of X_Q, if X_I≥0, the sign determination unit X associates the on-axis data with a value indicating the fourth quadrant and sets (A, B)=(+1, −1) and, if X_I<0, associates the on-axis data with a value indicating the second quadrant and sets (A, B)=(−1+1). In the case of absolute value of X_I<absolute value of X_Q, if X_Q≥0, the sign determination unit X associates the on-axis data with a value indicating the first quadrant and sets (A, B)=(+1, +1) and, if X_Q<0, associates the on-axis data with a value indicating the third quadrant and sets (A, B)=(−1, −1). In the case of absolute value of Y_I absolute value of Y_Q, if Y_I≥0, the sign determination unit Y associates the on-axis data with the value indicating the fourth quadrant and sets (A, B)=(+1, −1) and, if Y_I<0, associates the on-axis data with the value indicating the second quadrant and sets (A, B)=(−1, +1). In the case of absolute value of Y_I<absolute value of Y_Q, if Y_Q≥0, the sign determination unit Y associates the on-axis data with the value indicating the first quadrant and sets (A, B)=(+1, +1) and, if Y_Q<0, associates the on-axis data with the value indicating the third quadrant and sets (A, B)=(−1, −1).

That is, concerning the data of the inner shell, data on the positive side on the I axis is associated with the value indicating the fourth quadrant, data on the negative side on the I axis is associated with the value indicating the second quadrant, data on the positive side on the Q axis is associated with the value indicating the first quadrant, and data on the negative side on the Q axis is associated with the value indicating the third quadrant. This corresponds to a case in which phases of signal points of the data are rotated 45 degrees clockwise. Values of A, B, C, and D corresponding to the quadrants are output from the sign determination circuit 7.

Note that, concerning the data of the inner shell, the data on the positive side on the I axis can be associated with the value indicating the first quadrant, the data on the negative side on the I axis can be associated with the value indicating the third quadrant, the data on the positive side on the Q axis can be associated with the value indicating the second quadrant, and the data on the negative side on the Q axis can be associated with the value indicating the fourth quadrant. This corresponds to a case in which phases of signal points of the data are rotated 45 degrees counterclockwise. This state is illustrated in FIG. 11.

Subsequently, in step S4, the following processing is performed on the data of the outer shell. Concerning this processing, an example illustrated in FIG. 10 and an example illustrated in FIG. 11 are the same. In the case of X_I≥0, if X_Q≥0, the sign determination unit X determines (A, B)=(+1, +1) as the first quadrant and, if X_Q<0, determines (A, B)=(+1, −1) as the fourth quadrant. In the case of X_I<0, if X_Q≥0, the sign determination unit X determines (A, B)=(−1, +1) as the second quadrant and, if X_Q<0, determines (A, B)=(−1, −1) as the third quadrant. In the case of Y_I≥0, if Y_Q≥0, the sign determination unit Y determines (C, D)=(+1, +1) as the first quadrant and, if Y_Q<0, determines (C, D)=(+1, −1) as the fourth quadrant. In the case of Y_I<0, if Y_Q≥0, the sign determination unit Y determines (C, D)(−a, +1) as the second quadrant and, if Y_Q<0, determines (C, D)=(−1, −1) as the third quadrant.

Concerning the data of the outer shell of the 8QAM illustrated in FIG. 10 and FIG. 11, as in the QPSK, the outputs (A, B) and (C, D) of the sign determination units X and Y are the same as a result obtained by determining, on the reception side, with the hard determination, values indicating the quadrants.

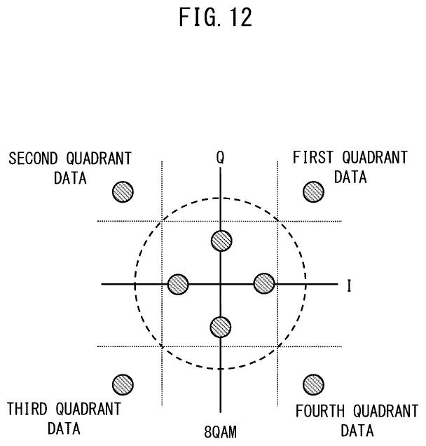

FIG. 12 is a diagram illustrating a comparative example of the sign determination of the 8QAM. In the comparative example, as in the QPSK or the 16QAM, hard determination is performed on signal points of the 8QAM by the I axis and the Q axis regardless of a power level.

In the case of the 8QAM, for eight signal points, concerning the four data of the outer shell, a hard determination result is directly a value indicating the first quadrant, a value indicating the second quadrant, a value indicating the third quadrant, and a value indicating the fourth quadrant and the signs (A, B) and (C, D) respectively corresponding to the values are output. However, concerning the four data of the inner shell, sign determination by a hard determination result is indefinite.

On the other hand, in the sign determination circuit 7 using the sign determination method illustrated in FIG. 6 and FIG. 7, in the case of the 8QAM illustrated in FIG. 10 and FIG. 11, concerning the four data of the outer shell, the hard determination result is directly signs associated with the quadrants. Further, concerning the four data of the inner shell, the sign determination by the hard determination result is not indefinite and the data are allocated to one quadrant among the four quadrants and determined as a sign associated with the quadrant.

Therefore, even in the case of a modulation scheme in which a part of data is mapped onto the I axis or the Q axis, the sign determination circuit 7 according to the present embodiment can securely determine a sign without involving indefinite determination. The sign determination circuit 7 can also perform averaging of the data. In correlation calculation using output of the sign determination circuit 7, the sign determination circuit 7 can stably calculate a correlation value and perform accurate comparison. As a result, the polarization separation monitor 3 including the sign determination circuit 7 can greatly reduce cases in which equivalence convergence is detected by mistake even for the case of the modulation scheme such as the 8QAM in which a part of data is mapped onto the I axis or the Q axis.

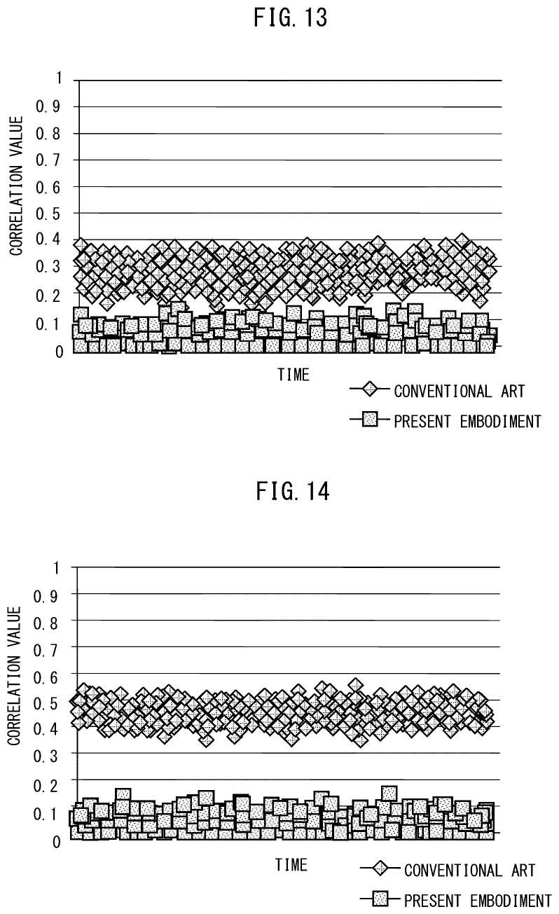

FIG. 13 to FIG. 16 are diagrams illustrating function evaluation results in the 8QAM of the adaptive equalization circuit according to the embodiment. The function evaluation results are obtained by measuring a correlation state in the correlation calculation circuit 8 of the polarization separation monitor 3. However, in the adaptive equalization circuit 27, all tap coefficients of four FIR filters in the digital filter 1 are in a state of having converged to a value with which polarization separation is correctly performed. Since the calculation of the tap coefficients has correctly converged, originally, it is desirable that a correlation value is a low value in the polarization separation monitor 3. When the correlation value is high, although the calculation of the tap coefficients converges, wrong detection indicating that the calculation has not converged is performed.

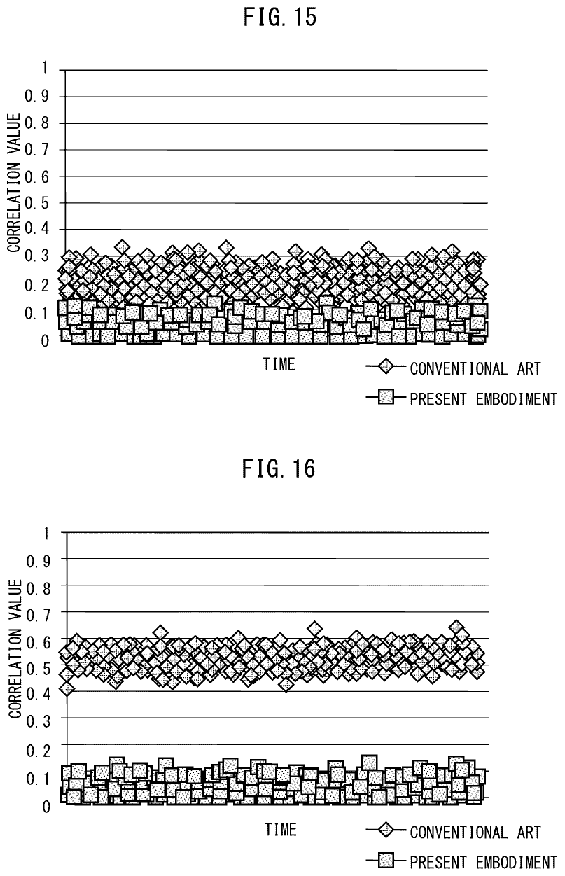

FIG. 13 illustrates a correlation value between the I-axis component X_I of the X polarization data and the I-axis component Y_I of the Y polarization data. FIG. 14 illustrates a correlation value between the I-axis component X_I of the X polarization data and the Q-axis component Y_Q of the Y polarization data. FIG. 15 illustrates a correlation value between the Q-axis component X_Q of the X polarization data and the I-axis component Y_I of the Y polarization data. FIG. 16 illustrates a correlation value between the Q-axis component X_Q of the X polarization data and the Q-axis component Y_Q of the Y polarization data. The vertical axis indicates the correlation value. I indicate that correlation is the largest and 0 indicates that correlation is absent. The horizontal axis indicates a time. In graphs, an upper graph (dots of black diamonds) indicates output of the correlation calculation circuit of the polarization separation monitor of the related art to which the present embodiment is not applied. A lower graph (dots of black squares) indicates output of the correlation calculation circuit 8 of the polarization separation monitor 3 according to the present embodiment.

The output of the correlation calculation circuit of the polarization separation monitor of the related art sometimes shows a numerical value of maximum 0.55 in FIG. 14 and a numerical value of 0.65 or more in FIG. 16 and a large correlation value is detected. If a comparative value of a correlation value in a comparison circuit is 0.5, it is seen that wrong detection is performed at a high frequency. If the wrong detection is performed, the polarization separation monitor 3 determines that equivalence convergence has occurred and notifies the control circuit 4. According to the notification, the control circuit 4 instructs the filter tap coefficient update circuit 2 to perform update again. Although the tap coefficient has converged to a value with which polarization separation is correctly performed, update work is performed again. Accordingly, the tap coefficient unnecessarily fluctuates and stable adaptive equalization processing is not performed.

On the other hand, output of the correlation calculation circuit 8 of the polarization separation monitor 3 according to the present embodiment is 0.2 or less in all the cases. If a comparative value of a correlation value in the comparison circuit 9 is 0.6, wrong detection does not occur. Accordingly, the polarization separation monitor 3 does not notify wrong information concerning equivalence convergence to the control circuit 4. Instructions of useless re-update from the control circuit 4 to the filter tap coefficient update circuit 2 can also be reduced. Accordingly, it is possible to continue stable adaptive equalization processing without the tap coefficient unnecessarily fluctuating.

As explained above, in an actual evaluation, effectiveness of the polarization separation monitor 3 according to the present embodiment can be confirmed. The adaptive equalization circuit 27 including the polarization separation monitor 3 according to the present embodiment can be adapted to all modulation schemes and can perform a stable polarization separation operation.

### REFERENCE SIGNS LIST

1 digital filter; 2 filter tap coefficient update circuit; 3 polarization separation monitor; 4 control circuit; 7 sign determination circuit; 8 correlation calculation circuit; 9 comparison circuit; 25 AD converter; 26 chromatic dispersion compensation circuit; 27 adaptive equalization circuit; 201 reception optical module

1. Adaptive equalization circuitry comprising:
a digital filter receiving a first polarization signal and a second polarization signal subjected to polarization separation and performing further polarization separation processing;
filter tap coefficient update circuitry updating a tap coefficient of the digital filter according to fluctuation in a polarization state;
a polarization separation monitor comparing a correlation value between the first polarization signal and the second polarization signal output from the digital filter with a predetermined value; and
control circuity causing the filter tap coefficient update circuitry to execute initial convergence of the tap coefficient again when the polarization separation monitor detects that the correlation value exceeds the predetermined value,
wherein the polarization separation monitor includes sign determination circuitry determining to which quadrant among four quadrants on a IQ plane the first polarization signal and the second polarization signal belong, correlation calculation circuitry calculating the correlation value from a determination result of the sign determination circuity, and comparison circuitry comparing the correlation value with the predetermined value, and
in case of a transmission modulation scheme in which on-axis data located on an I axis or a Q axis of the IQ plane is present in the first polarization signal and the second polarization signal, the sign determination circuitry extracts the on-axis data, and associates, without overlap, data on a positive side on the I axis, data on a negative side on the I axis, data on a positive side on the Q axis, and data on a negative side on the Q axis among the on-axis data respectively with one value among values indicating the four quadrants on the IQ plane.

2. The adaptive equalization circuitry according to claim 1, wherein the sign determination circuitry extracts the on-axis data based on magnitude of power of input data of the first polarization signal and the second polarization signal.

3. The adaptive equalization circuitry according to claim 2, wherein the magnitude of the power is estimated based on an addition value of absolute value of a coordinate value of the I axis and absolute value of a coordinate value of the Q axis of the data.

4. The adaptive equalization circuitry according to claim 1, wherein values indicating four quadrants on the IQ plane are respectively (+1, +1), (−1, +1), (−1, −1), and (+1, −1).

5. The adaptive equalization circuitry according to claim 1, wherein in an I-axis component and a Q-axis component of each of the first polarization signal and the second polarization signal, in a case of absolute value of I-axis component≥absolute value of Q-axis component, the on-axis data is associated with a value indicating the fourth quadrant if I-axis component≥0, and the on-axis data is associated with a value indicating the second quadrant if I-axis component<0, and
in a case of absolute value of I-axis component<absolute value of Q-axis component, the on-axis data is associated with a value indicating the first quadrant if Q-axis component≥0, and the on-axis data is associated with a value indicating the third quadrant if Q-axis component<0.

6. The adaptive equalization circuitry according to claim 1, wherein in an I-axis component and a Q-axis component of each of the first polarization signal and the second polarization signal, in a case of absolute value of I-axis component≥absolute value of Q-axis component, the on-axis data is associated with a value indicating the first quadrant if I-axis component≥0, and the on-axis data is associated with a value indicating the third quadrant if I-axis component<0, and
in a case of absolute value of I-axis component<absolute value of Q-axis component, the on-axis data is associated with a value indicating the second quadrant if Q-axis component≥0, and the on-axis data is associated with a value indicating the fourth quadrant if Q-axis component<0.

7. A reception device comprising:
a reception optical module converting a received optical signal into an electric signal;
an AD converter converting the electric signal into a digital signal;
chromatic dispersion compensation circuitry compensating for distortion due to chromatic dispersion of the digital signal; and
the adaptive equalization circuitry according to claim 1 performing equalization processing for compensating for distortion due to polarization fluctuation of an output signal of the chromatic dispersion compensation circuitry.

8. An adaptive equalization method comprising:
receiving a first polarization signal and a second polarization signal subjected to polarization separation and performing further polarization separation processing by a digital filter;
updating a tap coefficient of the digital filter according to fluctuation in a polarization state by filter tap coefficient update circuitry;
determining to which quadrant among four quadrants on a IQ plane the first polarization signal and the second polarization signal belong, calculating a correlation value between the first polarization signal and the second polarization signal, comparing the correlation value with a predetermined value, by a polarization separation monitor;
causing the filter tap coefficient update circuitry to execute initial convergence of the tap coefficient again by control circuitry, when the polarization separation monitor detects that the correlation value exceeds the predetermined value,
wherein in case of a transmission modulation scheme in which on-axis data located on an I axis or a Q axis of the IQ plane is present in the first polarization signal and the second polarization signal, the sign determination circuitry extracts the on-axis data, and associates, without overlap, data on a positive side on the I axis, data on a negative side on the I axis, data on a positive side on the Q axis, and data on a negative side on the Q axis among the on-axis data respectively with one value among values indicating the four quadrants on the IQ plane.
